(19) United States
(12) Patent Application Publication
(10) Pub. No.: US 2004/0111662 A1
(43) Pub. Date: Jun. 10, 2004

(54) Method of, and apparatus for, slicing a signal

(76) Inventors: Peter James Livermore, Nottingham (GB); Graham Butler, Nottingham (GB); John Stuart Hill, Nottingham (GB)

Correspondence Address: Alan Israel, Kirschstein Ottinger Israel & Schiffmiller, 489 Fifth Avenue, New York, NY, 10017-6105, US

(21) Appl. No.: 10/466,409

(22) PCT Filed: Jan. 15, 2002
(86) PCT No.: PCT/GB02/00147

(30) Foreign Application Priority Data
Jan. 15, 2001 (GB) 0101062.8

(51) Int. Cl. H03M 13/00

(52) U.S. Cl. 714/760

(57) ABSTRACT

A method of, and apparatus for, slicing a modulated input signal is disclosed. The method comprises: generating at least one slice threshold level (20); comparing (3) the magnitude of the input signal (1) with the at least one threshold level to produce a corresponding sliced signal having a first magnitude if the input signal is greater than the threshold level and having a second magnitude if the input signal is less than the threshold level. The method further comprises detecting errors (5) in the sliced signal and producing a corresponding error signal; and setting the threshold level in response to the error signal.

The present invention relates to a method of and an apparatus for slicing a signal. More especially, although not exclusively, the invention concerns a method of and apparatus for slicing an amplitude modulated communications signal to enable de-modulation of the signal.

Transmission of data usually involves encoding the data as a series of logic ones and zeros and transmitting a signal, whether optical, electrical or otherwise which is modulated with the series of logic ones and zeros. For example, a logic one may be represented by a high level signal (for example a high voltage level or a high light intensity) and a logic zero may be represented by a low level signal (for example a low voltage level or a low light intensity) or absence of a signal.

On receiving the modulated signal it is necessary to convert it into a signal representative of the original data. Therefore it is necessary to determine whether a given level of the received signal is representative of a logic one or a logic zero. Signals can, of course, suffer degradation through transmission by, for example, signal attenuation, noise or the like. Commonly the received signal is sliced by comparing the magnitude of the received signal with a slice, or threshold, level and outputting a signal whose magnitude is high (representative of a logic 1) if the magnitude of the input signal is above the slice level and is low (representative of a logic 0) if the magnitude of the input signal is below the slice level.

The value (magnitude) of the slice level can therefore affect the accuracy of the data represented by the de-modulated output signal compared to the original data represented by the transmitted signal.

When manufacturing a device that includes such a signal slicing circuit it is known to permanently program or pre-set the slice level at the time of manufacture for each such slicing circuit. Allowing signal slicing circuits manufactured to the same specification to have different slice levels assigned to them allows for the possibility of the circuit being assigned an optimum slice level allowing for differences in the properties of the signal slicing circuits owing to manufacturing tolerances. Typically the slice level will be set to a level that is at a constant proportion of the way between high and low levels measured for a test input signal. The proportion assigned varies from one device to another, but the ratio assigned to a given device is a constant value usually between 0.4 and 0.5 of the peak voltage of the input signal.

The present invention seeks to provide a method of and apparatus for slicing an input signal having an improved manner of setting the slice level used to slice the signal.

According to the present invention there is provided a method of slicing a modulated input signal comprising: generating at least one slice threshold level; comparing the magnitude of the input signal with the at least one threshold level to produce a corresponding sliced signal having a first magnitude if the input signal is greater than the threshold level and having a second magnitude if the input signal is less than the threshold level; detecting errors in the sliced signal and producing a corresponding error signal; and setting the threshold level in response to the error signal.

Thus the slice threshold level can be adjusted dynamically preferably with the aim of minimising errors. The slice threshold level is preferably altered in dependence on the rate of errors detected. The error signal therefore preferably includes information concerning the rate of detected errors.

The method can be such that if there is a very low error rate it is assumed that the slice threshold level is at or is close to the optimum level (corresponding to a minimum error rate) and does not therefore need to be significantly changed. Correspondingly the method can be such that if there is a relatively high error rate it is assumed that there is a better slice threshold level corresponding to a lower error rate and that therefore the slice threshold level should be changed by a relatively large amount in order to quickly reach a slice threshold level corresponding to a lower error rate.

Conveniently, the method can be used when slicing a modulated input signal that includes both source data and error detection information. The step of detecting errors in the sliced signal, and producing an error signal in response to said detection of errors, may in that case involve making use of that error detection information.

The method can be used to advantage where there are more than two predetermined magnitudes of the sliced signal, in which case there are more than one slice threshold level. However, the method is of particular advantage where the input signal is representative of a binary signal (i.e. having two states) and in such a case there is preferably a single dynamically alterable slice threshold level.

The error signal preferably includes information concerning the type of errors detected. Such information may then be used when changing the slice threshold level.

The method advantageously includes the steps of extracting the source data from the sliced signal, detecting errors, and correcting those errors. In the case where the input signal comprises error detection information, errors in the source data may be corrected in view of such error detection information. Of course, the method may be such that, when performing those steps, errors in the error detection information are also effectively detected and corrected. The error signal preferably depends on the errors detected irrespective of whether the errors relate to the source data or to the error detection information.

In an embodiment of the method of the invention operating on a binary input signal the error signal includes information indicative of (a) a logic “0” being sliced erroneously as logic “1” (hereinafter referred to as errored zeros) and (b) a logic “1” being sliced erroneously as logic “0” (hereinafter referred to as errored ones).

The error signal may, for example, be representative of the respective rates of errored zeros and ones. Alternatively, the error signal may be representative of the ratio of the rates of errored zeros and ones. However, the error signal is preferably simply representative of the balance of errored zeros to errored ones over a given period of time. The period of time may simply be from the start of operation until the instant at which the given error signal is produced.

The error signal may be used to indicate whether the slice threshold level should be increased or decreased. The amount by which the slice threshold level is changed may be a predetermined amount. The predetermined amount may effectively be manually adjustable.

Given that the general relationship between the rate of errors detected compared with the slice threshold level could be represented by a notional curve having a minimum at the optimum slice threshold level, the slice threshold level may be changed in response to the errors detected in a manner taking advantage of mathematical methods used to find efficiently the minimum of such a curve. For example, the slice value could rapidly be brought close to the optimum value by using a Newton-Raphson method.

Preferably, the method includes a step where the slice threshold level is initially set. The initial slice threshold level may depend on a manually preset level. The method may also effectively include a step in which a decision is made as to whether the method should be started again using a preset slice threshold level. Such a step would enable the slice threshold level to be reset if, for example, a fault occurs (for example, the error rate becomes very high).

The step of detecting errors in the sliced signal conveniently makes use of a forward error correction (FEC) algorithm.

The input signal can be an electrical signal derived from an optical communications signal.

The method may include a step of searching for a better slice threshold level during a period in which the rate of errors being detected is very low. When the quality of the input signal is high, relatively low error rates will be observed even if the slice threshold level is not near the theoretical optimum level. If the quality of transmission suddenly deteriorates, the fact that the slice threshold level is significantly different from the optimum level may result in a period of greatly increased errors in the sliced signal. Searching for a better slice threshold level during a period in which the rate of errors being detected is very low can pre-empt such a situation. Preferably, the step of searching for a better slice threshold level is only performed after a period in which the detected error rate is less than 1 error detected per 10⁶ bits received. More preferably, in the case where the method includes a step of correcting detected errors, the searching step is only performed after a period when the error rate is such that the corrected data contains on average less than 1 error in every 10¹⁵ bits and yet more preferably when the error rate is sufficiently low that the corrected data is substantially error free.

Preferably, during the step of searching for a better slice threshold level, the error rate is not caused to increase significantly. For example, provided that the quality of transmission remains substantially constant, the error rate is maintained preferably below a certain rate, and more preferably (in the case where the method includes a step of correcting detected errors) below an error rate corresponding to the corrected data being substantially error free. Preferably, the step of searching for a better slice threshold level includes the steps of: varying the slice threshold level from a first level, at which the rate of errors being detected is relatively low, (a) to a second level higher than the first, at which the rate of errors being detected is some particular rate higher than said relatively low rate, and (b) to a third level lower than the first, at which the rate of errors being detected is some particular rate higher than said relatively low rate, and then changing the slice level to a level between the second and third levels calculated from those levels.

For example, there may be a first step in which the slice threshold level is increased (to the second level) until the rate of errors being detected rises above a predetermined threshold, and a second step in which the slice threshold level is reduced (to the third level) until the rate of errors being detected rises above the predetermined threshold, the slice threshold level thereafter being set to a level midway between the second and third levels. The predetermined error rate threshold is preferably such that the error rate is sufficiently low that substantially all of the errors are correctable.

The slice threshold level could alternatively be set at a level between the second and third levels taking into account the rate of change of the rate of errors detected. For example, the new slice threshold level may then be chosen to be at a level calculated to correspond to a minimum (and not therefore necessarily exactly halfway between the second and third levels) error rate.

The present invention also provides an apparatus for slicing a modulated input signal comprising: slice threshold generator for generating at least one slice threshold level; a signal slicer for comparing the magnitude of the input signal with the at least one threshold level to produce a corresponding sliced signal having a first magnitude if the input signal is greater than the threshold level and having a second magnitude if the input signal is less than the threshold level; an error detector for detecting errors in the sliced signal and producing a corresponding error signal; and means for setting the threshold level in response to the error signal.

The apparatus may for example be formed of a suitably programmed processor that performs the function of each of the signal slicer, the slice threshold level signal generator, and the error detector. Alternatively, dedicated electronic components may perform the functions of the signal slicer and the error detector.

The signal slicer may comprise a comparator having as its inputs the said input signal and the slice threshold level.

The slice threshold level generator may comprise a preponderance counter which is incremented in response to one of said type of errors (those being errored ones and errored zeros) and is decremented in response to the other thereby providing a measure of which type is in preponderance.

The slice threshold level generator may comprise a slice threshold counter the value of which is adjusted in response to the error signal and may comprise a digital to analogue converter responsive to the value of the counter to provide the slice threshold level.

The apparatus may be so arranged that the slice threshold counter is incremented if one of said types of errors is in preponderance and is decremented if the other is in preponderance as indicated by the preponderance counter.

The apparatus may be so arranged that the slice threshold level counter is incremented or decremented whenever one or other of said types of error occur.

The error detector may comprises an error corrector operative to correct the detected errors.

Of course the method of the present invention can be performed making use of such an apparatus. Furthermore, the apparatus can be so arranged as to be able to perform a method according to the present invention as described above.

An embodiment of the present invention will now be described, by way of example only, with reference to the accompanying drawings of which:

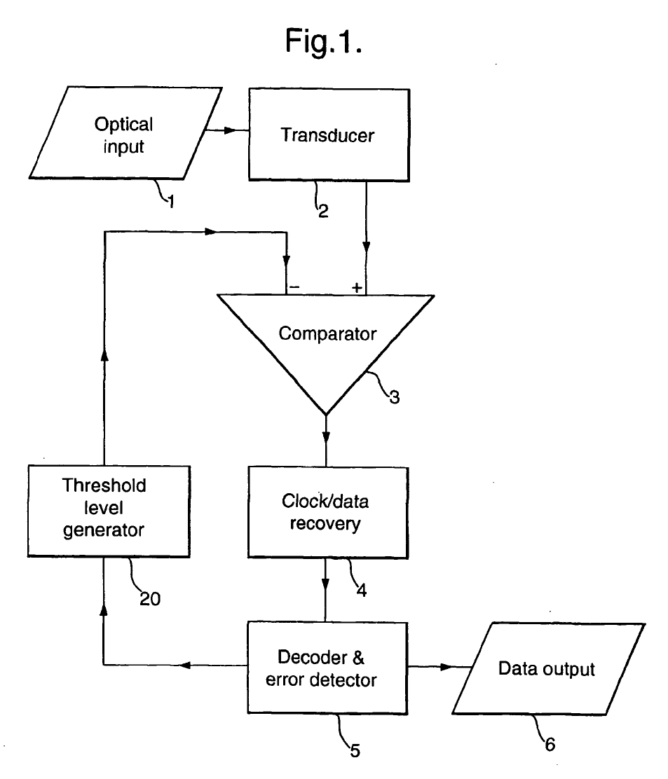

FIG. 1 is a schematic block diagram of a receiver arrangement for de-modulating a modulated input signal;

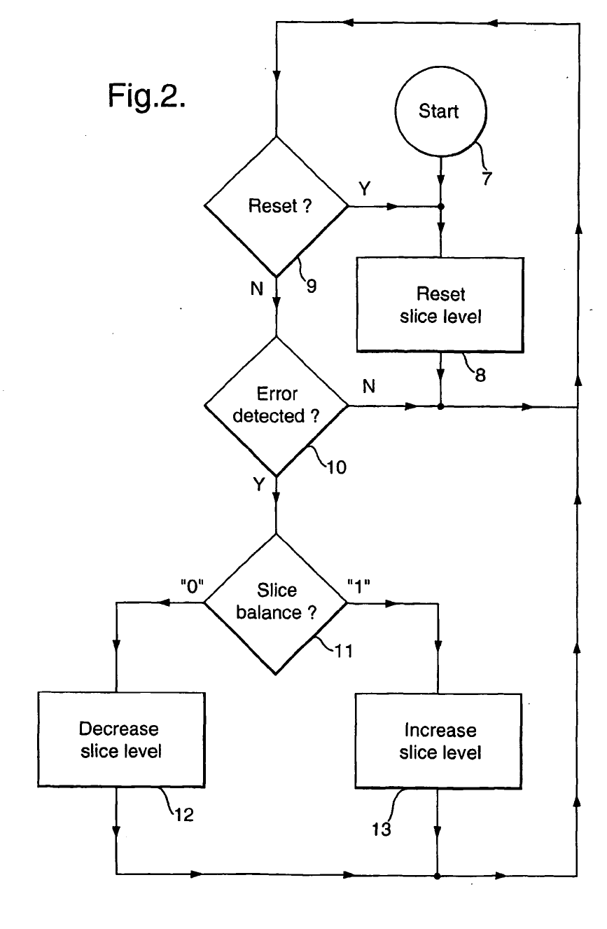

FIG. 2 is a flow chart illustrating a method of setting a threshold slicing level in accordance with the invention; and

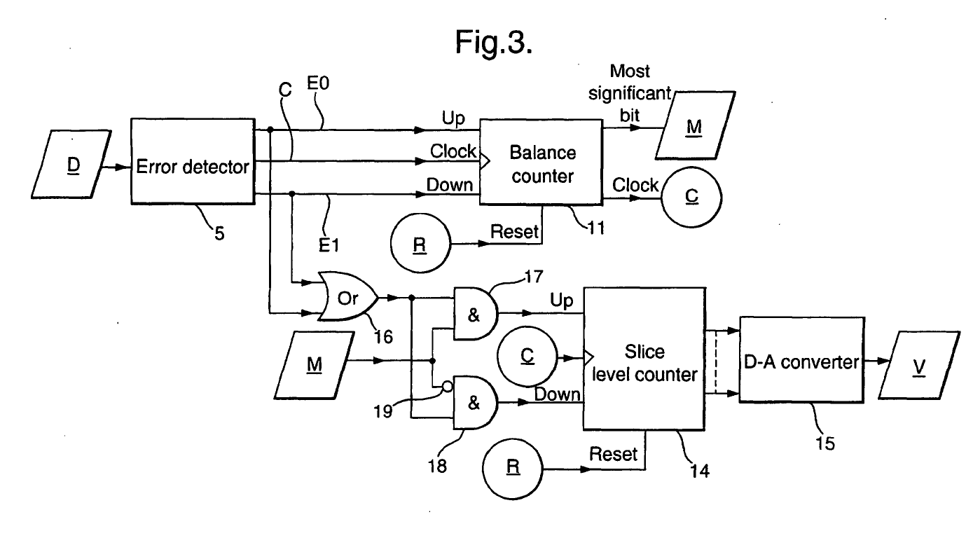

FIG. 3 is a block diagram illustrating a circuit for setting a threshold slicing level in accordance with the method illustrated by FIG. 2.

The exemplary embodiment of the invention relates to an optical transmission system, for example a wavelength division multiplex (WDM) system, in which data comprising logic ones and zeros is transmitted in the form of a modulated optical signal. As is known the modulated optical signal is typically generated by modulating optical radiation produced by a laser source using for example a Mach-Zehnder optical modulator connected to the output of the laser. The amplitude modulation is such that, on initial transmission, a logic 1 is represented by a pulse of light at maximum intensity and a logic 0 is represented by transmitting light at a low intensity. Ideally, a logic 0 would be represented by not transmitting any light, but such an arrangement is difficult to attain in practice due to limitations of the modulator.

Prior to modulating the data on to the optical radiation carrier (hereinafter such data will be referred to as the client data), the client data is encoded to form wrapped data including error detection information so that a receiver of the transmitted modulated optical signal can decode the signal and detect and correct errors in the wrapped data received by using a forward error correction (FEC) algorithm. (The wrapped data may also include other housekeeping information.) The use of an FEC algorithm reduces the need to request retransmission of data that has been corrupted during transmission of the data, since the errors are generally correctable at the receiving end. (Correction of the errors, as opposed to detecting them, is not essential to the present invention but is, of course, desirable for its own sake.)

FIG. 1 shows a schematic block diagram illustrating the components of a receiver arrangement for recovering and processing data from a modulated optical input signal. An optical input signal 1 which has been modulated with wrapped data (i.e. the data is contained within frames which include a block of client data and error detection information) is received by an optical to electrical transducer 2, which comprises an avalanche photo-diode circuit and an electric signal amplifier. The transducer 2 converts the optical signal into a corresponding amplified electrical input signal.

The electrical input signal output by the transducer 2 is applied to a first input of a comparator 3. A slice threshold voltage is generated by a threshold level generator 20 and applied to the second input of the comparator 3. The comparator 3 outputs a sliced electrical signal (D) that comprises first and second predetermined voltages (conveniently the second predetermined voltage is equal to ground potential). The first and second predetermined levels are thus easily distinguishable from each other. The comparator 3 slices the input signal by comparing the magnitude (voltage) of the electrical input signal with that of the slice threshold voltage; if the magnitude of the input signal is higher than the slice voltage then the comparator outputs the first (high) predetermined voltage, whereas if the magnitude of the input signal is lower than the slice voltage then the signal output is at the second (low) predetermined voltage.

The sliced signal D output by the comparator 3 is applied to a data recovery means 4. The data recovery means 4 recovers a clocked signal representing pulses of logic zeros and logic ones from the sliced signal by means of a phase lock loop. Such methods are well known in the art and, as such, are not described in further detail here.

The data represented by the clocked signal output by the data recovery means 4 is decoded by a combined decoder and error detector 5. The combined decoder and error detector 5 performs an FEC algorithm to detect and correct errors in the received data. The combined decoder and error detector 5 outputs an error corrected signal representative of output client data 6 (corresponding to the original client data) retrieved from the optical input signal 1. The combined decoder and error detector 5 also produces information concerning the errors detected.

The system shown schematically in FIG. 1 uses the information concerning the detected errors to set the slice threshold voltage generated by the threshold level generator 20 with the aim of optimizing the accuracy of the slicing of the input signal, as is explained further with reference to FIG. 2.

The FEC method used in the embodiment illustrated by the Figures makes use of a known Reed-Solomon algorithm using a data structure in accordance with the draft International Telecommunications Union specification ITU-T G709 published in March 2000. Accordingly, packets of data are transmitted as 16,320 byte super-frames comprised of 4 frames, each frame having 16 sub-frames of 255 bytes. The data is wrapped as a 255/239 data structure; that is, 255 bytes are required to wrap 239 bytes of payload (or client data), the difference (the overhead) of 16 bits being attributable to the extra space required for the inclusion of error detection and correction information. The data structure also contains 16 levels of interleaving so as to maximize error detection and correction capabilities if transmission were degraded by a burst of errors. Such a data structure allows the correction of up to a maximum of 8 byte errors in every 255 byte errors and allows for the correction of a burst of 1024 bit errors in a given frame. Transmission rates of data are such that one super-frame may be transmitted in 12.25 microseconds (i.e. at a rate of about 10¹⁰ bits/sec.).

Typically, during normal transmission operating conditions, the bits received will be substantially free of errors. If conditions are such that, for example, the error rate is one in 10⁹ the use of an FEC algorithm may reduce the number of errors in the client data after error correction substantially to zero.

FIG. 2 illustrates the method (flow diagram) by which the threshold level generator 20 sets the slice threshold voltage. With reference to FIG. 2, initially (starting from a start point 7) the slice threshold voltage is set at an initial level by a slice voltage reset means 8. The initial slice voltage is chosen to be halfway between the expected voltage representative of a logic 1 and the expected voltage representative of a logic 0.

After the slice voltage has been initially set, a reset decision means 9 ascertains whether the slice voltage needs to be reset. The slice voltage is reset if a fault occurs such as a loss of input signal, a phase lock loop error occurs in the data recovery means 4, an out of frame error, or the like. If the reset decision means 9 decides that the slice voltage should be reset (a “yes” decision—see the “Y” arrow leading from box 9) the slice voltage reset means 8 resets the slice voltage as described above.

When normal operation is attained (i.e. there are no major faults present) the reset decision means 9 decides that the slice voltage does not need to be reset (a “no” decision—see the “N” arrow leading from box 9). Then, an error detection means 10 ascertains whether there is a detectable error in the wrapped data that has been received. If no errors are detected (a “no” decision—see the “N” arrow leading from box 10) the slice voltage is assumed to be at an optimum level and is left unchanged. The process is then repeated, starting again at the reset decision means 9.

If, on the other hand, an error in a bit of information is detected by the error detection means 10 (a “yes” decision—see the “Y” arrow leading from box 10), the slice voltage is altered in an attempt to reach an optimum level. A decision is then made as to whether the slice voltage should be increased or decreased. A slice balance counter 11 (described in more detail with reference to FIG. 3) outputs a logic “1” if the slice voltage should be increased, and a logic “0” if the slice voltage should be decreased. Thus if a logic “0” is output the slice voltage is decreased by a predetermined amount by means of a slice voltage decreasing means 12 and if a logic “1” is output the slice voltage is increased by a predetermined amount by means of a slice voltage increasing means 13. Thereafter the process is repeated, starting again at the reset decision means 9.

FIG. 3 illustrates in greater detail how the slice level optimization method shown in FIG. 2 is implemented. The sliced electrical signal D including client data, error correction information and a clock signal is received by the combined decoder and error detector 5 (also shown in FIG. 1). The combined decoder and error detector 5 outputs client data (not shown in FIG. 3) as explained above with reference to FIG. 1. The circuit shown in FIG. 3 includes a slice level counter 14. The slice level counter 14 is a 16-bit counter without underflow or overflow, the count (a number from 0 to 65,535) being representative of the current slice threshold level. (Thus an instruction to increase the count from 65,535 or to reduce the count from 0 results in the count remaining unchanged.) A digital output representing the current count (i.e. representative of the current slice level) held in the counter 14 is received by a digital to analogue converter 15, which outputs an analogue voltage V in proportion to the slice level count. A buffer means (not shown) receives the voltage V and outputs the slice threshold level voltage for use by the converter 3 (not shown in FIG. 3) to slice its input signal as explained above with reference to FIG. 1. The buffer means both amplifies and offsets the voltage V. For example, input voltages ranging from 0 to 0.5V could be output in a range from 1.5V to 2.5V (a gain of 2 and an offset of 1.5V).

The combined decoder and error detector 5 outputs a clock signal C and two error signals E0 and E1. If no errors are detected error signals E0 and E1 are both representative of a logic 0. If an error is detected a single clock pulse representing a logic 1 is output; if the error is that a logic 1 has been decoded when the relevant bit should have been a logic 0 (i.e. an errored zero) the error signal E0 pulses high (a logic 1), whereas if the error is that a logic 0 has been decoded when the relevant bit should have been a logic 1 (i.e. an errored one) the error signal E1 pulses high.

The error signals E0 and E1 and the clock signal are received by a slice balance counter 11 (also shown in FIG. 2). The slice balance counter 11 is a binary 12-bit modulo up/down counter. Thus the number represented by the 12 bits held in the counter may range from 0 to 4095 and counting up from 4095 yields 0, whereas counting down from 0 yields 4095. Initially (or on a reset) the 12-bit number held in the counter 11 is set to 2048. The most significant bit M of the 12 bit number held by the counter (equal to a “0” if 0≦ count≦2047 and a “1” if 2048≦count≦4095) is output by the slice balance counter 11.

If the slice balance counter 11 receives a logic 1 pulse on the error signal E0 then the counter 11 causes an increment, so that if an errored zero is detected the number held by counter 11 is increased by 1. Similarly, if the slice balance counter 11 receives a logic 1 pulse on the error signal E1 then the counter causes an decrement, so that if an errored one is detected the number held by counter is decreased by 1. Thus if during operation more errored zeros are detected than errored ones the counter will tend to increase.

The error signals E0 and E1 from the decoder and error detector 5 are passed to a logic OR gate 16, the output of which therefore being high when an error is detected and low otherwise. A first logic AND gate 17 receives the output from the OR gate 16 and the output from the slice balance counter representing the most significant bit M of the count. A second logic AND gate 18 receives the output from the OR gate 16 and an inverted output from the slice balance counter representing the most significant bit M of the count, the inversion being performed by a logic NOT gate 19 at the input on the AND gate 18.

The outputs of the AND gates 17, 18 are received together with a clock signal C by the slice level counter 14. A high output from the first AND gate 17 causes the slice level counter 14 to increment, and a high output from the second AND gate 18 causes the slice level counter 14 to decrement. Thus if M is “1” and an errored zero or an errored one is detected the slice level counter 14 increments, whereas if M is “0” and an error is detected the slice level counter decrements.

If the count of the slice balance counter 11 is greater than or equal to 2048 the most significant bit M will be 1. Thus, if either an errored zero or an errored one is detected the slice level count, and therefore the voltage V, will be increased. If there is a period in which more errored ones are being detected than errored zeros (indicating that the slicing voltage is too high), then the count of the slice balance counter 11 will decrease, but whilst the most significant bit M remains a “1” the slice level counter will continue to increase. Once the count of the slice balance counter 11 has decreased below 2048 the most significant bit M will be a “0” and any detected errors will cause the slice level counter 14 to decrease the slice level. The slice voltage will therefore move closer to the optimum slice voltage (where the number of errored ones and the number of errored zeros are at a minimum and are roughly equal to each other).

One way of implementing the digital to analogue converter 15 is to use a pulse code modulated signal whose duty cycle is varied in dependence upon the count and to low pass filter this signal to produce the voltage V. Such an arrangement can be implemented readily using a field programmable gate array and provides adequate digital to analogue conversion.

If a system fault is detected, for example, by the reset decision means 9 (shown in FIG. 2) a reset signal R is sent to both the slice balance counter 11 and to the slice level counter 14. The slice threshold voltage is therefore reset if a fault occurs such as a loss of input signal, a phase lock loop error occurs in the data recovery means 4, an out of frame error, or the like. Such a reset signal is sent when the reset decision means 9 decides that the slice voltage should be reset (as described above with reference to FIG. 2).

The system as described above is able to establish quickly a slice threshold voltage at or close to the optimum on start up of an optical signal receiving circuit. The system is able to alter dynamically the slice threshold voltage during operation if the slice threshold voltage is no longer sufficiently close to the optimum level.

As will be appreciated various modifications can be made to the system described above without departing from the spirit of the present invention.

The system could search for the optimum slice threshold voltage using a more sophisticated searching method. For example, the system could use a Newton-Raphson method in order to minimize a notional error-slice voltage curve, in which case the system would ascertain the ratio of errored zeros to errored ones over a relatively small variation in slice voltage and then obtain an indication of the rate of change of that ratio with respect to the slice voltage and also the rate of change of the rate of change.

If the initial setting of the slice level counter 14 produces a slice threshold voltage that is greatly different from the optimum voltage there is a possibility that the slice balance counter will overflow, thereby inverting the most significant bit M and reversing the direction of the change of the slice voltage, before the slice voltage has reached the optimum voltage. There are several ways in which the illustrated system could be altered to reduce the chance of that happening. The size of the slice balance counter 11 could be increased from a 12-bit counter to, say, a 16-bit counter or the slice balance counter 11 could be prevented from overflowing.

There are integrated circuits commercially available that perform FEC algorithms and output a pulsed high for each error that is corrected (without distinguishing between errored ones and errored zeros) and output an indication of the balance of errored ones to errored zeros. In one implementation of the invention using such a circuit these signals are processed by a field programmable gate array designed by specifying it in VHDL (which is an IEEE standard) or in some other high level synthesis language (e.g. Verilog). The circuit of FIG. 3 is thus fully compatible with such commercially available chips, in that the output indicative of a given error is represented by the OR gate 16 and the output indicative of the error balance is represented by the signal of the most significant bit M of the slice balance counter 11. The balance counter of the commercially available chip is one without overflow or underflow i.e. one whose value increments from its maximum value to its minimum and vice versa. A counter which would saturate, i.e. not increase beyond its maximum value or decrease below its minimum, would be preferred but the problem of reaching under or overflow may be avoided by making the balance counter large enough; conveniently that of the commercial chip is programmable in size.

The embodiment of FIG. 3 could, of course, also operate by removing the OR gate 16 and the corresponding inputs to the AND gates 17, 18 by feeding the error signal E0 directly to the input of first AND gate 17 and feeding the error signal E1 directly to the input of second AND gate 18. The effect of this would be to reduce the effect of the slice voltage overshooting the optimum level. For example, consider the case where the most significant bit M of the slice balance counter 11 is equal to zero (indicating that more errored ones have been detected than errored zeros) and the slice threshold voltage then becomes much lower than the optimum slice threshold level (leading to more errored zeros being detected than errored ones). Whilst the slice balance counter is increasing towards 2048 (and M is still therefore equal to 0) the slice threshold voltage will be further decreased (i.e. further away from the optimum level) on detection of errors. With the circuit modified as mentioned above however, the slice threshold voltage will only be further decreased, when an errored one is detected (which whilst the slice threshold voltage further decreases below the optimum level will become increasingly unlikely). Thus, the tendency of overshooting the optimum threshold slice level is reduced.

As mentioned above, on start up or reset, the slice voltage is initially set to a suitable level. Whilst the slice level may be set to a halfway value, the buffer means (not shown) connected to the output of the digital to analogue converter 15 may be arranged such that a slice level of half minimum to maximum corresponds to a slice voltage of less than half of the minimum to maximum of the incoming signal. The noise attributable to the signals representing logic ones in the incoming signal is much greater to the noise on logic zeros. Therefore the optimum slice voltage is generally between 30% and 50% of the signal trough to peak.

The system could also be arranged to hunt for a better slice voltage despite the detected error rate being very low. When signal quality is high the system may erroneously maintain the slice voltage at a substantially constant voltage that is relatively far removed from the theoretical optimum voltage. Whist the client may receive error free data whilst the transmission is of high quality, if the quality of transmission is suddenly reduced more errors than necessary may require correction (in a worse case scenario leading to so many errors that a proportion pass through undetected). The system can therefore be arranged to preempt such a situation as follows. During a period of low error detection (i.e. the received data is substantially error free) the slice voltage is reduced so that the error rate eventually rises to a predetermined threshold, which is still low enough that the client data is error free. From that first voltage, the slice voltage is then increased to a second voltage where the error rate has again reached the predetermined threshold. The optimum slice voltage is then set at the voltage halfway between the first and second voltages corresponding to the error rate threshold. The slice voltage thereby set should therefore be closer to the optimum slice voltage so that high performance can be maintained even if transmission suddenly deteriorates.

The FEC algorithm used acts on a relatively large data packet (frame). There may therefore be more than one error detected for each cycle of operation. In that case, a series of clocked pulses may be output from the combined decoder and error detector after the end of the packet, the number of pulses corresponding to the number of errors detected. Of course, the clock pulses are at a sufficiently high frequency that the alteration of the slice threshold voltage is completed before the next cycle of operation.

Further whilst the invention has been described in relation to a method of and apparatus for slicing a binary signal (i.e. one having two logic states) using a single slicing threshold level it will be appreciate that the invention can also be applied to systems using multilevel received signals to set two or more threshold levels.

1. A method of slicing a modulated input signal which includes both source data and forward error correction (FEC) information, the method comprising: generating at least one slice threshold level; comparing the magnitude of the input signal with the at least one threshold level to produce a corresponding sliced signal having a first magnitude indicative of a logic “0” if the input signal is greater than the threshold level and having a second magnitude indicative of a logic “0” if the input signal is less than the threshold level, characterised by detecting errors in the sliced signal using the error correction information and producing corresponding error signals (E0, E1) indicative of a rate of logic “0s” being sliced erroneously as logic “1s” (E1) and a rate of logic “1s” being sliced erroneously as logic “0s” (E0); and setting the threshold level in response to the error signals (E0, E1) such as to substantially minimise the number of logic “1s” and “0s” being sliced erroneously.

2. A method as claimed in claim 1, and comprising determining if there is a preponderance of logic “0”s being sliced erroneously as logic “1”s or of logic “1”s being sliced erroneously as logic “0”s , and, in response, raising the slice threshold level, if the preponderance is of logic “0”s sliced erroneously as logic “1”s, and lowering the slice threshold level, if the preponderance is of logic “1” a sliced erroneously as logic “0”s .

3. A method according to any preceding claim, and further comprising: extracting source data form the sliced signal, detecting errors; correcting those errors using the forward error correction information and searching for a better slice threshold level during a period in which the rate of errors after error correction is substantially zero.

4. A method according to any preceding claim, and further comprising searching for a better slice threshold level by: varying the slice threshold level from a first level, at which the rate of errors being detected is relatively low, (a) to a second level higher than the first, at which the rate of errors being detected is some particular rate higher than said relatively low rate and (b) to a third level lower than the first, at which the rate of errors being detected is some particular rate higher than said relatively low rate, and then changing the slice level to a level between the second and third levels calculated from those levels.

5. Apparatus for slicing a modulated input signal, the input signal including both source data and forward error correction (FEC) information, the apparatus comprising: a slice threshold generator (20) for generating at least one slice threshold level (V); a signal slicer (3) for comparing the magnitude of the input signal with the at least one threshold level to produce a corresponding sliced signal having a first magnitude indicative of a logic “1” if the input signal is greater than the threshold level and having a second magnitude indicative of a logic “0” if the input signal is less than the threshold level; characterised by an error detector (5) for detecting errors in the sliced signal using the error correction information and producing error signals (E0, E1) indicative of a rate of logic “0s” being sliced erroneously as logic “1s” (E1) and a rate of logic “1s” being sliced erroneously as logic “0s” (E0); and means (14, 16-19) for setting the threshold level in response to the error signals (E0, E1) such as to substantially minimise the number of logic “1s” and “0s” being sliced erroneously.

6. Apparatus according to claim 5, wherein the slice threshold generator includes means (11) for determining from the error signals whether there is a preponderance of logic “0”s being sliced erroneously as logic “1”s or of logic “1”s being sliced erroneously as logic “0”s, and, in response, to raise the slice threshold level, if the preponderance is of logic “0”s sliced erroneously as logic “1”s, and to lower the slice threshold level, if the preponderance is of logic “1”s sliced erroneously as logic “1”s.

7. Apparatus according to claim 6, wherein the means (16-19) for determining whether there is a preponderance of logic “0s” or “1s” erroneously sliced comprises a counter which is incremented in response to one of said error signals and is decremented in response to the other error signal.

8. Apparatus according to any one of claims 5 to 7, wherein the slice threshold level generator (20) comprises a slice threshold counter (14) so arranged that the value of the slice threshold counter is adjusted in response to the error signals and a digital to analogue converter (15) responsive to the value of the counter and arranged to provide the slice threshold level (V).

9. Apparatus according to claim 8 when dependent on claim 7, which is so arranged that the slice threshold counter (14) is incremented if one of said types of errors is in preponderance and is decremented if the other is in preponderance as indicated by the preponderance counter.

10. Apparatus according to claim 9 which is so arranged that the slice threshold level counter is incremented or decremented whenever one or other of said types of error occur.

11. Apparatus according to any one of claims 5 to 10, wherein the error detector includes an error corrector operative to correct the detected errors; and is arranged to search for a better slice threshold level during a period in which the rate of errors after error reaction is substantially zero.

12. Apparatus according to any one of claims 5 to 11 arranged to (i) vary the slice threshold level from a first level, at which the rate of errors being detected is relatively low, (a) to a second level higher than the first, at which the rate of errors being detected is some particular rate higher than said relatively low rate, and (b) to a third level lower than the first, at which the rate of errors being detected is some particular rate higher than said relatively low rate, and then (ii) to change the slice level to a level between the second and third levels calculated from those levels.
